(19) United States
(12) Patent Application Publication
(10) Pub. No.: US 2004/0009409 A1
(43) Pub. Date: Jan. 15, 2004

(54) Optical proximity correction method

(76) Inventors: Jiunn-Ren Hwang, Hsin-Chu City (TW); Jui-Tsen Huang, Taipei City (TW); Chang-Jyh Hsieh, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 10/064,413

(22) Filed: Jul. 11, 2002

(51) Int. Cl. G03F 1/00; G06F 17/50

(52) U.S. Cl. 430/5; 716/19

(57) ABSTRACT

An optical proximity correction (OPC) method first provides a predetermined integrated circuit layout. The integrated circuit layout is then formed on a surface of a photo-mask, and a plurality of nonprintable dummy patterns are formed outside the integrated circuit layout on the surface of the photo-mask. The plurality of dummy patterns are used to reduce the difference in pattern density on the surface of the photo-mask so as to modify optical proximity effect, and the dummy patterns are not transferred to a photoresist layer formed on a semiconductor wafer during a photolithography process.

### BACKGROUND OF INVENTION

1. Field of the Invention

The present invention relates to an optical proximity correction (OPC) method, and more particularly, to an OPC method using dummy patterns to reduce the difference in pattern density.

2. Description of the Prior Art

In semiconductor manufacturing processes, in order to transfer an integrated circuit layout onto a semiconductor wafer, the integrated circuit layout is first designed and formed as a photo-mask pattern. The photo-mask pattern is then proportionally transferred to a photoresist layer positioned on the semiconductor wafer.

As the design pattern of integrated circuit becomes smaller and due to the resolution limit of the optical exposure tool, optical proximity effect will easily occur during the photolithographic process for transferring the photo-mask pattern with higher density. The optical proximity effect will cause defects when transferring the photo-mask pattern, such as right-angled corner rounding, line end shortening, and line width increasing/decreasing. U.S. Pat. No. 6,042,973 to Pierrat and U.S. Pat. No. 6,077,630 to Pierrat describe forming a subresolution grating composed of approximately circular contacts around the border of the primary patter of a photo-mask. As a result, resolution at the edges of the photo-mask pattern is improved when the pattern is printed on a wafer surface. However, the subresolution grating is not able to suppress the optical proximity effect when transferring the photo-mask pattern. Therefore, in order to avoid the above-mentioned defects caused by the optical proximity effect, the semiconductor process uses a computer system to perform an optical proximity correction (OPC) method of the integrated circuit layout. The corrected integrated circuit layout is then designed as a photo-mask pattern and is formed on a surface of the photo-mask.

Please refer to FIG. 1 to FIG. 4. FIG. 1 to FIG. 4 are schematic diagrams of a prior art OPC method. As shown in FIG. 1, an original integrated circuit layout 10 comprises a plurality of line figures 12 for defining word lines. In order to avoid the defects of line end shortening and line width increasing/decreasing caused by the optical proximity effect when transferring the line figures 12, a computer system is used to perform an OPC method of the integrated circuit layout 10. As shown in FIG. 2, the photo-mask pattern 14 is a result of the integrated circuit layout 10 of FIG. 1 after correcting by the prior art OPC method. As well, as shown in FIG. 3, an original integrated circuit layout 16 comprises a plurality of rectangular figures 18 for defining doped regions. In order to avoid the defects of right-angled corner rounding caused by the optical proximity effect when transferring the rectangular figures 18, a computer system is used to perform an OPC method of the integrated circuit layout 16. As shown in FIG. 4, the photo-mask pattern 20 is a result of the integrated circuit layout 16 of FIG. 3 after correcting by the prior art OPC method.

The prior art OPC method only uses one OPC model to correct the whole integrated circuit layout, and the factor of different pattern density in local regions of the photo-mask resulting in overexposure or underexposure is not taken into consideration. Furthermore, as the system on chip (SOC) is developed, many different kinds of semiconductor devices (such as memory, logic circuits, Input/Output, and central processing unit) are integrated and formed on one chip for substantially reducing costs and improving speed. Therefore, the pattern density of integrated circuit layout is very different in local regions of the chip, and the prior art OPC method is not applicable.

### SUMMARY OF INVENTION

It is therefore a primary objective of the claimed invention to provide an OPC method for solving the above-mentioned problems.

According to the claimed invention, an optical proximity correction (OPC) method is provided. The method first provides a predetermined integrated circuit layout. The integrated circuit layout is then formed on a surface of a photo-mask, and a plurality of transparent nonprintable dummy patterns are formed outside the integrated circuit layout on the surface of the photo-mask. The plurality of transparent dummy patterns are used to reduce the difference in pattern density on the surface of the photo-mask so as to modify optical proximity effect, and the dummy patterns are not transferred to a photoresist layer formed on a semiconductor wafer during a photolithography process because of a phase difference of 180 degrees between a transmitted light of the integrated circuit layout and a transmitted light of the dummy patterns.

It is an advantage over the prior art that the OPC method of the claimed invention forms a plurality of nonprintable dummy patterns around an integrated circuit layout predetermined to be transferred on a substrate. The dummy patterns are used to reduce the difference in pattern density of the integrated circuit layout for correcting optical proximity effect. Furthermore, the dummy patterns are designed by performing a simple operation according to conditions of a photolithographic process. Therefore, the time cost of a complicated operation performed by the prior art OPC method can be substantially reduced.

These and other objectives of the claimed invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 to FIG. 4 are schematic diagrams of a prior art OPC method.

FIG. 5 to FIG. 6 are schematic diagrams of an OPC method according to the present invention method.

### DETAILED DESCRIPTION

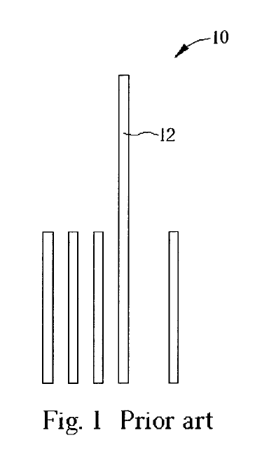

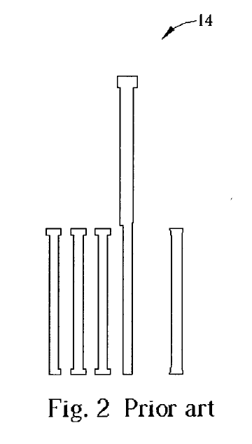

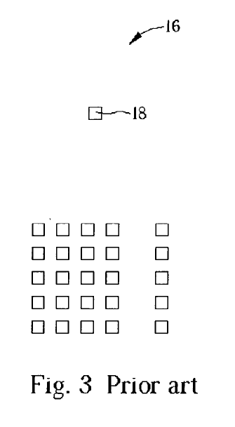

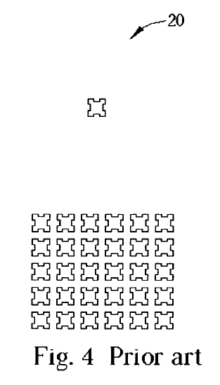

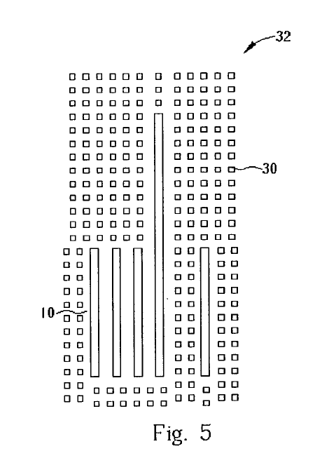

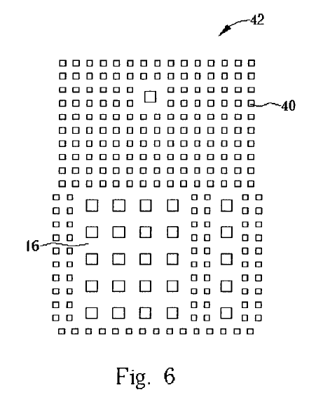

Please refer to FIG. 5 and FIG. 6. FIG. 5 and FIG. 6 respectively depict the integrated circuit layouts 10, 16 of FIG. 1 and FIG. 3 after correcting by an OPC method according to the present invention method. As shown in FIG. 5, according to the present invention method, the integrated circuit layout 10 predetermined to be transferred to a substrate (not shown), such as a semiconductor wafer, is directly formed on a surface of a photo-mask (not shown). Moreover, a plurality of dummy patterns 30 of rectangular figures are formed outside the integrated circuit layout 10 on the surface of the photo-mask, and the integrated circuit layout 10 and the dummy patterns 30 together compose a photo-mask pattern 32. In other words, the present invention method first uses a computer system to perform an optical proximity correction of the integrated circuit layout 10 predetermined to be transferred to a substrate by forming a plurality of nonprintable dummy patterns 30 in a blank region outside the integrated circuit layout 10. The integrated circuit layout 10 and the plurality of nonprintable dummy patterns 30 are then simultaneously fabricated on the surface of the photo-mask so as to reduce the difference in pattern density of the integrated circuit layout 10. According to one embodiment of the present invention, the dummy patterns 30 are only fabricated around the integrated circuit layout 10. According to another embodiment of the present invention, the dummy patterns 30 are fabricated and distributed over the blank region outside the integrated circuit layout 10, as shown in FIG. 5.

As well, as shown in FIG. 6, the integrated circuit layout 16 predetermined to be transferred to a substrate is directly formed on a surface of a photo-mask. Moreover, a plurality of dummy patterns 40 of rectangular figures are formed outside the integrated circuit layout 16 on the surface of the photo-mask, and the integrated circuit layout 16 and the dummy patterns 40 together compose a photo-mask pattern 42.

In another embodiment of the present invention method, a computer system is first used to perform a prior art OPC of the integrated circuit layouts 10, 16 for preventing the pattern transferring defects, such as right-angled corner rounding, line end shortening, and line width increasing/decreasing. A plurality of nonprintable dummy patterns are then formed in a blank region outside the corrected integrated circuit layouts. Finally, the corrected integrated circuit layouts and the plurality of nonprintable dummy patterns are simultaneously fabricated on a surface of a photo-mask so as to reduce the difference in pattern density of the integrated circuit layouts 10, 16.

The integrated circuit layouts 10, 16 of FIG. 5 and FIG. 6 will be transferred from the photo-mask to a photoresist layer formed on a surface of the substrate by a pattern transferring process, such as a photolithographic process. Therefore, in a preferred embodiment of the present invention, the dimensions and the numbers of the dummy patterns 30, 40 are designed according to exposure wave length and numerical apertures of the pattern transferring process and the materials included in the photoresist layer for reducing the difference in pattern density of the integrated circuit layouts 10, 16 and modifying the optical proximity effect. Another important design factor of the dummy patterns 30, 40 is that a phase difference of 180 degrees is detected between a transmitted light of the integrated circuit layout 10, 16 and a transmitted light of the dummy patterns 30, 40, and the dummy patterns 30, 40 will not be transferred to the photoresist layer during the photolithographic process. In FIG. 5 and FIG. 6 for example, the edge length of dummy patterns 30, 40 of rectangular figures is a multiple of exposure wave length, and the multiple is less than 0.6. The distance between each of the dummy patterns 30, 40 is also a multiple of exposure wave length, and the multiple ranges between 0.3 and 2.0. As well, the least distance between the integrated circuit layout 10, 16 and the dummy patterns 30, 40 is a multiple of exposure wave length, and the multiple ranges between 0.4 and 2.0.

Briefly speaking, the OPC method of the claimed invention forms a plurality of nonprintable dummy patterns around an integrated circuit layout predetermined to be transferred to a substrate. The dummy patterns are used to reduce the difference in pattern density of the integrated circuit layout for modifying optical proximity effect. Comparing to the prior art OPC method, the dummy patterns of the present invention are designed by performing a simple operation according to conditions of a photolithographic process. Therefore, the time cost of a complicated operation performed by the prior art OPC method can be substantially reduced.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An optical proximity correction (OPC) method for reducing optical proximity effect occurring in a pattern transferring process, the method comprising:
providing a photo-mask;
providing an original photo-mask pattern predetermined to be formed on a surface of the photo-mask, the original pattern comprising at least one integrated circuit layout and at least one blank region;
forming a plurality of dummy patterns in the blank region, the integrated circuit layout, the plurality of dummy patterns, and the residual blank region together composing a corrected photo-mask pattern; and
forming the corrected photo-mask pattern on the surface of the photo-mask;
wherein a phase difference of 180 degrees is detected between a transmitted light of the integrated circuit layout and a transmitted light of the dummy patterns.

2. The method of claim 1 wherein the plurality of dummy patterns are used to reduce the difference in pattern density of the original photo-mask pattern so as to modify optical proximity effect occurring in a pattern transferring process.

3. The method of claim 1 wherein the plurality of dummy patterns are fabricated around the integrated circuit layout.

4. The method of claim 1 wherein the plurality of dummy patterns are fabricated and distributed over the blank region.

5. The method of claim 1 wherein the integrated circuit layout is transferred to photoresist layer formed on a surface of a substrate by the pattern transferring process.

6. The method of claim 5 wherein the plurality of dummy patterns are nonprintable dummy patterns and not transferred to the photoresist layer during the pattern transferring process.

7. The method of claim 6 wherein the dimensions and the numbers of the dummy patterns are designed according to exposure wave length and numerical apertures of the pattern transferring process and the materials included in the photoresist layer.

8. The method of claim 7 wherein the edge length of each dummy pattern is a multiple of exposure wave length, and the multiple is less than 0.6.

9. The method of claim 7 wherein the distance between each dummy pattern is a multiple of exposure wave length, and the multiple ranges between 0.3 and 2.0.

10. The method of claim 7 wherein the least distance between the dummy patterns and the integrated circuit layout is a multiple of exposure wave length, the multiple ranges between 0.4 and 2.0.

11. A method of forming patterns on a surface of a photo-mask, the method comprising:
providing a photo-mask; and
forming an integrated circuit layout on the surface of the photo-mask, and forming a plurality of dummy patterns outside the integrated circuit layout on the surface of the photo-mask;
wherein a phase difference of 180 degrees is detected between a transmitted light of the integrated circuit layout and a transmitted light of the dummy patterns.

12. The method of claim 11 wherein the plurality of dummy patterns are used to reduce the difference in pattern density on the surface of the photo-mask so as to modify optical proximity effect occurring in a pattern transferring process.

13. The method of claim 12 wherein the integrated circuit layout is transferred to a photoresist layer formed on a surface of a substrate by the pattern transferring process.

14. The method of claim 12 wherein the plurality of dummy patterns are nonprintable dummy patterns and not transferred to the photoresist layer during the pattern transferring process.

15. The method of claim 14 wherein the dimensions and the numbers of the dummy patterns are designed according to exposure wave length and numerical apertures of the pattern transferring process and the materials included in the photoresist layer.

16. The method of claim 15 wherein the edge length of each dummy pattern is a multiple of exposure wave length, and the multiple is less than 0.6.

17. The method of claim 15 wherein the distance between each dummy pattern is a multiple of exposure wave length, and the multiple ranges between 0.3 and 2.0.

18. The method of claim 15 wherein the least distance between the dummy patterns and the circuit layout is a multiple of exposure wave length, the multiple ranges between 0.4 and 2.0.

19. An optical proximity correction (OPC) method for reducing optical proximity effect occurring in a pattern transferring process, the method comprising:
providing a photo-mask;
providing an integrated circuit layout predetermined to be formed on a surface of the photo-mask;
performing a partial OPC of the integrated circuit layout for obtaining a corrected integrated circuit layout; and
forming the corrected integrated circuit layout on the surface of the photo-mask and forming a plurality of dummy patterns outside the corrected integrated circuit layout on the surface of the photo-mask.

20. The method of claim 19 wherein the partial OPC is used to modify pattern transferring defects of the integrated circuit layout comprising right-angled corner rounding, line end shortening, and line width increasing/decreasing.

21. The method of claim 19 wherein the plurality of dummy patterns are used to reduce the difference in pattern density on the surface of the photo-mask so as to modify optical proximity effect occurring in a pattern transferring process.

22. The method of claim 19 wherein the plurality of dummy patterns are nonprintable dummy patterns and not transferred to a photoresist layer formed on a surface of a substrate during the pattern transferring process, however, the integrated circuit layout is transferred to the photoresist layer by the pattern transferring process.

23. The method of claim 22 wherein the dimensions and the numbers of the dummy patterns are designed according to exposure wave length and numerical apertures of the pattern transferring process and the materials included in the photoresist layer.

24. The method of claim 23 wherein the edge length of each dummy pattern is a multiple of exposure wave length, and the multiple is less than 0.6.

25. The method of claim 23 wherein the distance between each dummy pattern is a multiple of exposure wave length, and the multiple ranges between 0.3 and 2.0.

26. The method of claim 23 wherein the least distance between the dummy patterns and the integrated circuit layout is a multiple of exposure wave length, the multiple ranges between 0.4 and 2.0.
